(19) United States
(12) Patent Application Publication
(10) Pub. No.: US 2024/0208712 A1
(43) Pub. Date: Jun. 27, 2024

(54) Module Packaging Pieces for Packaging Using Alternating Module Orientations

(71) Applicant: Maxeon Solar Pte. Ltd., Singapore (SG)

(72) Inventors: Elizabeth Schulte, Virginia Beach, VA (US); Lee Gorny, Tenafly, NJ (US); Jose Cornelio Flores, Digos City (PH); Cho Hui Khim, Singapore (SG); Nur Diyanah Zaid, Singapore (SG)

(21) Appl. No.: 18/088,568

(22) Filed: Dec. 25, 2022

(51) Int. Cl. B65D 81/05; B65D 81/133; B65D 85/48; B65D 85/62

(52) U.S. Cl. CPC B65D 81/053; B65D 81/133; B65D 85/48; B65D 85/62

(57) ABSTRACT

A module packaging piece is disclosed. The module packaging piece includes a first side that includes one or more flange securing tabs and a first channel that is configured to accommodate and constrain a flange of a frame of a first module. The module packaging piece includes a second side that includes a second channel that is configured to accommodate and constrain a flange of a frame of a second module.

### TECHNICAL FIELD

Embodiments of the disclosure pertain to packaging pieces, and more particularly to packaging pieces that enable packaging using alternating module orientations.

### BACKGROUND

A photovoltaic module or solar panel is an assembly of photovoltaic cells mounted and organized in a framework for generating energy. Solar panels use sunlight as a source of energy to generate direct current electricity. An AC (alternating current) module is a photovoltaic module which has an AC inverter mounted onto its back side and which produces AC power with no external DC connector. In order to complete successful shipping projects, solar panels need to be packaged in a manner that prevents damage. This is because damage related shipping and packaging costs can contribute significantly to the overall cost of a project. Some current trends in the solar panel industry present challenges to the prevention of such damage.

One such trend involves the reduction of frame heights to increase shipping density, and to reduce shipping costs. The reduction of frame height can present clearance issues for AC solar panel modules that have thick AC Microinverters (ACMI) installed on the modules at the factory. Specifically, because the height of the AC solar panel module frame may not extend a sufficient distance outward from the panel to accommodate the height of thick ACMIs, the ACMI may protrude below the bottom of the AC solar panel module. Importantly, the protruding ACMI can contact adjacent solar panels in a manner that causes damage to the adjacent solar panels during shipping. Thus, AC solar panel modules that have frame heights that are less than the heights of their ACMIs, can present challenges to the packaging of the AC solar panel modules in a way that prevents damage to adjacent AC solar panel modules during shipping and handling. Moreover, conventional packaging methods may be inadequate to provide packaging that can prevent damage to AC solar panel modules during shipping for AC solar panel modules that have frames with heights that are less than the heights of their ACMIs.

### BRIEF DESCRIPTION OF THE DRAWINGS

FIG. 1A shows a short side perspective of a solar panel module stack that uses an alternating sunny side up and sunny side down arrangement of modules according to one embodiment.

FIG. 1B shows a long side perspective of a solar panel module stack that uses an alternating sunny side up and sunny side down arrangement of modules according to one embodiment.

FIG. 1C is an exploded view of modules that shows the relative positions of the modules, their ACMIs and packaging pieces according to one embodiment.

FIG. 1D illustrates the relative positions of an exemplary set of four frame-to-frame packaging pieces with respect to the backsheet side of a sunny side up module according to one embodiment.

FIG. 1E illustrates the relative positions of an exemplary set of four glass-to-glass packaging pieces with respect to the glass component of a sunny side down module according to one embodiment.

FIG. 1F shows a perspective view of a frame-to-frame packaging piece according to one embodiment.

FIG. 1G shows a perspective view of a frame-to-frame packaging piece according to one embodiment.

FIG. 1H shows a perspective view of a glass-to-glass packaging piece according to one embodiment.

FIG. 1I shows a perspective view of a glass-to-glass packaging piece according to one embodiment.

FIG. 1J shows a perspective view of a glass-to-glass packaging piece according to one embodiment.

FIG. 1K shows cross sections of a conventional module frame and an exemplary module frame according to one embodiment.

FIG. 1L shows a manner in which forces can act on horizontally stacked modules according to one embodiment.

FIG. 1M shows the manner in which frame-to-frame package pieces provide reaction forces that keep horizontally stacked modules stable according to one embodiment.

FIG. 1N shows the manner in which frame-to-frame package pieces provide reaction forces that keep horizontally stacked modules stable according to one embodiment.

FIG. 1O shows a manner in which forces can act on horizontally stacked modules according to one embodiment.

FIG. 1P shows the manner in which glass-to-glass package pieces provide reaction forces that keep horizontally stacked modules stable according to one embodiment.

FIG. 1Q shows the manner in which glass-to-glass package pieces provide reaction forces that keep horizontally stacked modules stable according to one embodiment.

FIG. 2A shows a flowchart of a method of forming a packaging piece according to one embodiment.

FIG. 2B shows a flowchart of a method of forming a packaging piece according to one embodiment.

### DESCRIPTION OF THE EMBODIMENTS

Packaging pieces that enable packaging using alternating module orientations are described. It should be appreciated that although embodiments are described herein with reference to example packaging piece implementations, the disclosure is applicable to packaging piece implementations in general as well as other kinds of packaging piece implementations. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As used herein, the term “module” is intended to refer to a photovoltaic module or solar panel.

As used herein, the term “glass components” refer to the glass and associated photovoltaic elements and encapsulant that can be attached together as a unit to the frame of a module.

As used herein, the term “interface” is intended to refer to the area between facing frames, or facing glass components, of frame-to-frame or glass-to-glass oriented modules.

As used herein, a “short side” is intended to refer to one of the two sides of a rectangular module or stack of modules that is shorter than the longer sides of the rectangular module or stack of modules.

As used herein, the term “long side” is intended to refer to one of the two sides of a rectangular module or stack of modules that is longer than the shorter sides of the rectangular module or stack of modules.

As used herein the term “sunny side” is intended to refer to the side of a photovoltaic module that is designed to face a light source and to receive light.

As used herein a reference to the “face” or “front” of a photovoltaic module is intended to refer to the sunny side of the photovoltaic module.

As used herein a reference to the “back” of a photovoltaic module is intended to refer to the side of the photovoltaic module opposite the “face” of the photovoltaic module.

As used herein the term “glass-to-glass” is intended to refer to a face-to-face orientation of a pair of photovoltaic modules.

As used herein the term “frame-to-frame” is intended to refer to a back-to-back orientation of a pair of photovoltaic modules.

As used herein, the term “backsheet” side is intended to refer to the back side of a photovoltaic module (the side that does not face a light source), that includes a backsheet that protects the inner components of the photovoltaic module. In one embodiment, as regards bifacial modules, glass can be used on the back side of the photovoltaic module instead of a backsheet.

As used herein the term “channel” is intended to refer to a trench that is formed in a packaging piece that is configured to firmly hug either a flange or a lip of a module frame.

As used herein the term “package” is intended to refer to one or more modules that are bundled and/or boxed for storage or transit.

As used herein the term “packaging” is intended to refer to the act of creating a package of modules.

As used herein, the term “pack” is intended to refer to one or more vertically or horizontally placed modules. A pack of one module would include a single module vertically or horizontally disposed. A pack of two or more modules would comprise two or more either vertically or horizontally disposed modules for packaging.

As used herein the term “packing,” or, to “pack” is intended to refer to the act of placing one or more modules either vertically or horizontally together for packaging.

As used herein, the term “stack” is intended to refer to a pile of horizontally oriented modules that can be used in the preparation of a package. As used herein to “stack” is intended to refer to the act of piling a plurality of horizontally oriented modules for use in the preparation of a package.

As used herein the term “full quantity of modules” is intended to refer to the number of modules that is necessary to fill what is considered to be a full package of modules.

As used herein the term “partial quantity of modules” is intended to refer to a number of modules that is less than that which is necessary to fill what is considered to be a full package of modules.

As used herein the term “full package” of modules is intended to refer to a package of modules that contains the number of modules that is considered to completely fill the package of modules.

As used herein the term “partial package” of modules is intended to refer to a package of modules that contains a number of modules that is less than that which is considered to completely fill the package of modules.

As used herein the term “packaging piece” or “module packaging piece” is intended to refer to a device that can be firmly fastened or clipped to the frame of a first module and which provides a channel for restraining the movement of a second module.

As used herein, a number that is preceded by a capital letter “F” or “G” is intended to refer to a packaging piece. For example, the reference numbers F103 and G103 are intended to refer generally to frame-to-frame and glass-to-glass packaging pieces respectively. More specifically, if the reference number F103 or G103 does not include a subscript or a number enclosed in parentheses, the frame-to-frame or glass-to-glass packaging piece identified represents frame-to-frame or glass-to-glass packaging pieces in general.

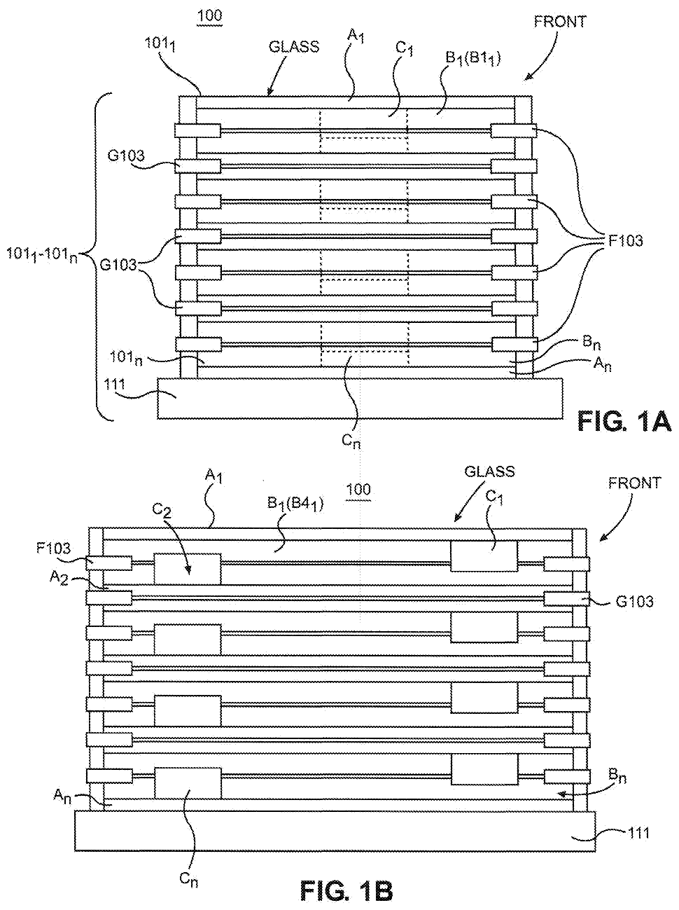

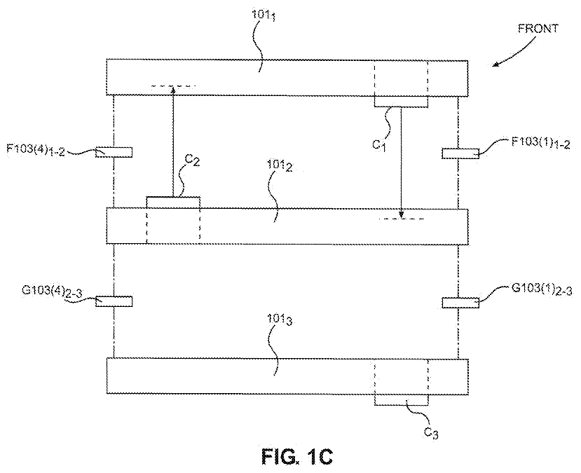

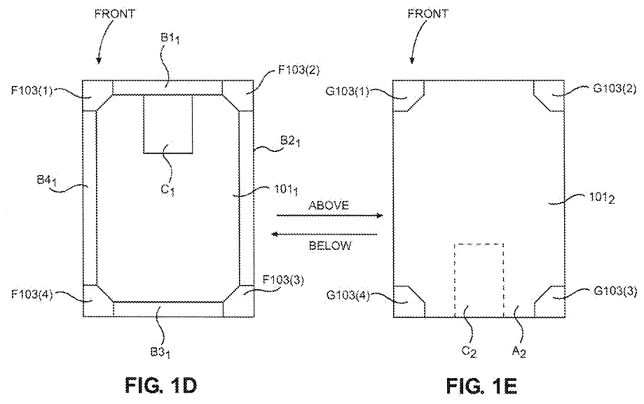

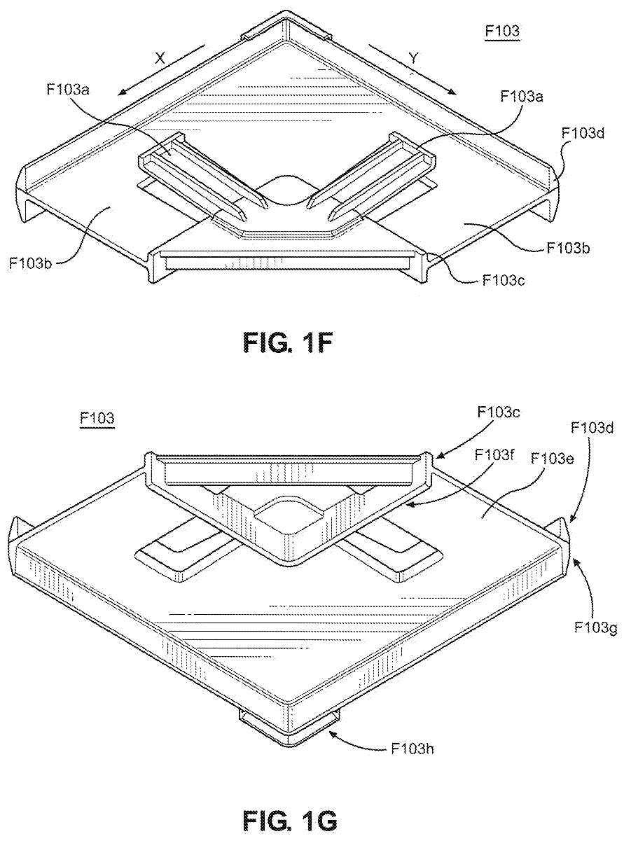

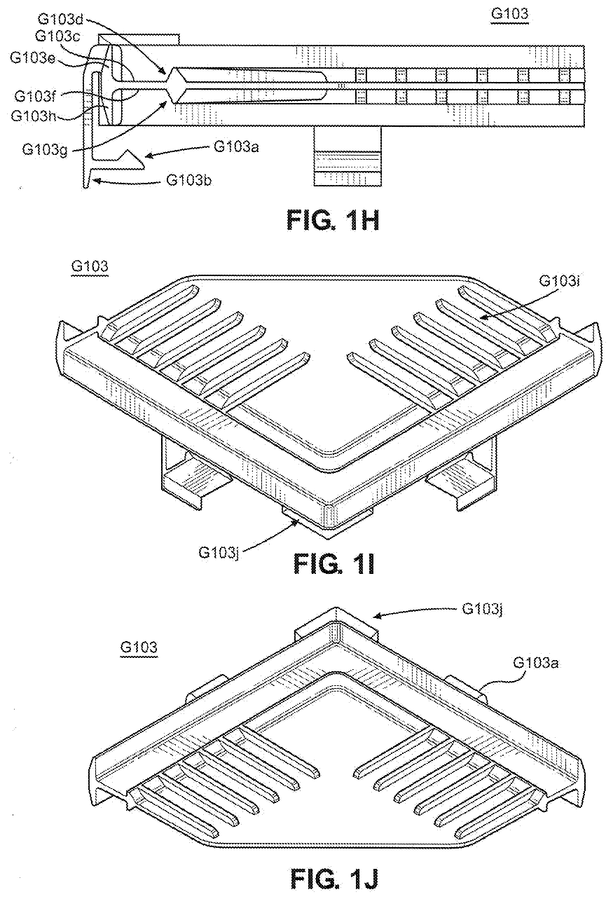

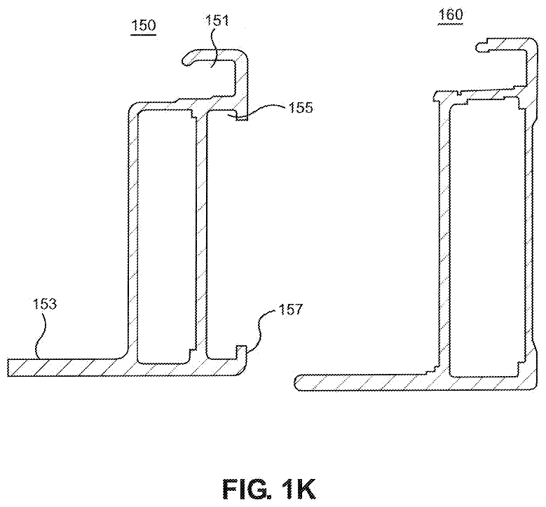

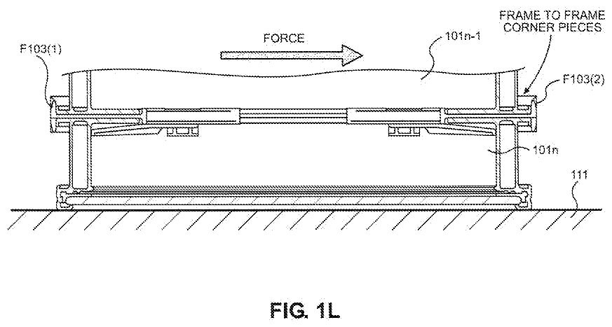

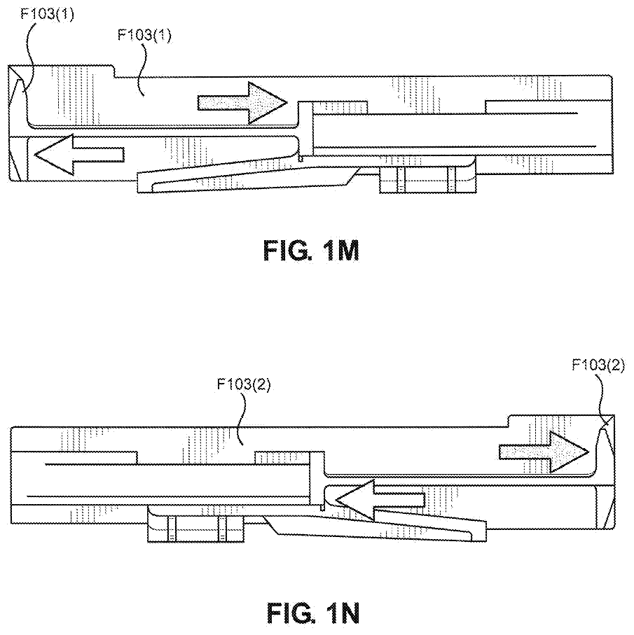

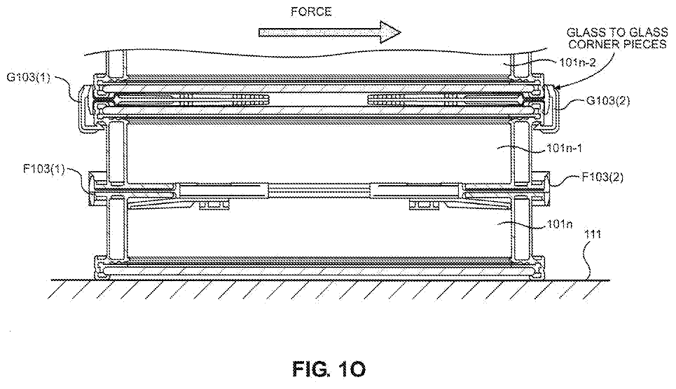

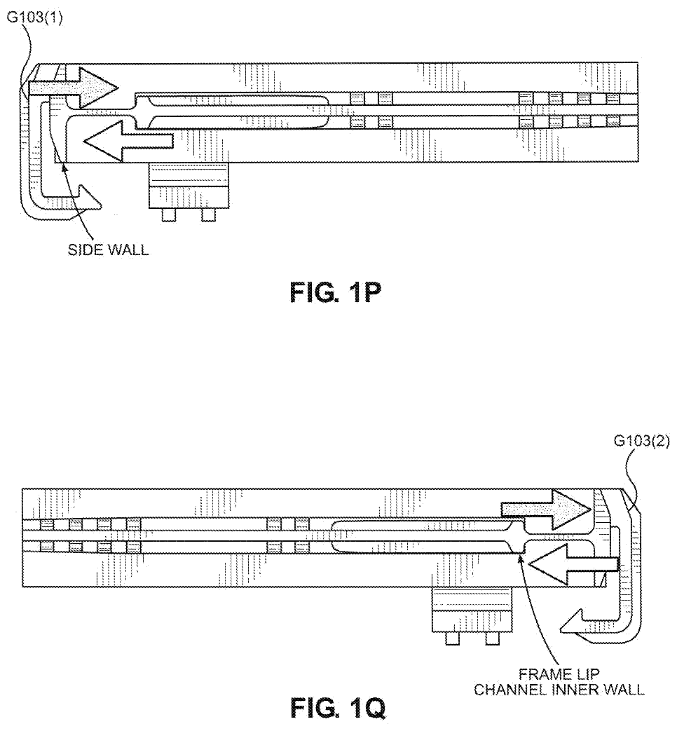

For purposes of clarity and brevity the reference number for specific frame-to-frame and glass-to-glass packaging pieces used in a stack of alternating sunny side up and sunny side down modules is based on the position of the packaging pieces with respect to the downward oriented side of the upper positioned module of the pairs of modules in the stack of modules that share either a frame-to-frame or a glass-to-glass interface. For example, as used herein, the reference numbers F103 or G103 of a packaging piece followed by a number enclosed by a parenthesis such as “(1)” is intended to indicate the position of the packaging piece with respect to the downward oriented side of an upper positioned module of a pair of modules that share a frame-to-frame or a glass-to-glass interface. In particular, as used herein “(1)” refers to the left top corner of the downward oriented side of an upper positioned module of a pair of modules that share a frame-to-frame or a glass-to-glass interface, “(2)” refers the right top corner of the downward oriented side of an upper positioned module of a pair of modules that share a frame-to-frame or a glass-to-glass interface, “(3)” refers to the right bottom corner of the downward oriented side of an upper positioned module of a pair of modules that share a frame-to-frame or a glass-to-glass interface, and “(4)” refers to the left bottom corner of the downward oriented side of an upper positioned module of a pair of modules that share a frame-to-frame or a glass-to-glass interface. This is reference scheme is illustrated in FIGS. 1D and 1E.

Thus, as used herein, a reference to F101(1) refers to the frame-to-frame packaging piece that is positioned at the left top corner of the downward oriented side of an upper positioned module of a pair of modules that share a frame-to-frame interface, F101(2) refers to the frame-to-frame packaging piece that is positioned at the right top corner of the downward oriented side of an upper positioned module of a pair of modules that share a frame-to-frame interface, F103(3) refers to the frame-to-frame packaging piece that is positioned at the right bottom corner of the downward oriented side of an upper positioned module of a pair of modules that share a frame-to-frame interface, and F103(4) refers to the frame-to-frame packaging piece that is positioned at the left bottom corner of the downward oriented side of an upper positioned module of a pair of modules that share a frame-to-frame interface (see FIG. 1D).

Similarly, as regards glass-to-glass packaging pieces, as used herein, a reference to G101(1) refers to the glass-to-glass packaging piece that is positioned at the left top corner of the downward oriented side of an upper positioned module of a pair of modules that share a glass-to-glass interface, G101(2) refers to the glass-to-glass packaging piece that is positioned at the right top corner of the downward oriented side of an upper positioned module of a pair of modules that share a glass-to-glass interface, G103(3) refers to the glass-to-glass packaging piece that is positioned at the right bottom corner of the downward oriented side of an upper positioned module of a pair of modules that share a glass-to-glass interface, and G103(4) refers to the glass-to-glass packaging piece that is positioned at the left bottom corner of the downward oriented side of an upper positioned module of a pair of modules that share a glass-to-glass interface (see FIG. 1E).

As used herein, subscripts associated with a module's reference number indicate the position of the module in a stack of modules. For example, the subscript 3 in the reference number 101₃, indicates that the identified module is the third module (as counted from the top of the stack of modules) in the stack of modules. As used herein, subscripts associated with a glass component's reference letter identifies the modules that the referenced glass component is associated with. For example, the subscript 1 in the reference character A₁, indicates that the identified glass component is associated with the first module in the stack of modules. As used herein, subscripts associated with a frame's reference letter identifies the module that the referenced frame is associated with. For example, the subscript 1 in the reference character B₁, indicates that the identified frame is associated with the first module in the stack of modules. As used herein, subscripts associated an AC Microinverter's (ACMI's) reference letter identifies the module that the referenced AC Microinverter (ACMI) is associated with. For example, the subscript 1 in the reference character ACMI₁, indicates that the identified ACMI is associated with the first module in the stack of modules. As used herein, subscripts associated with package pieces indicate the position of the package pieces in a stack of a plurality of modules. For example, as used herein, reference number F103(2)₁₋₂ refers to the frame-to-frame packaging piece F103 positioned at the right top corner position (2) of module 101₁ at the frame-to-frame interface between sunny side up module 101₁ and sunny side down module 101₂. In one embodiment, lower case letters that are used as a part of reference numbers herein refer to specific structural features of a packaging piece (see FIGS. 1F-1J).

An objective of module packaging is to prevent the packaged modules from being damaged during shipping and transport. Shipping and packaging costs that are attributable to damage incurred during shipping and transport can contribute significantly to the overall cost of a project. Reducing frame height to increase shipping density is a measure that can be taken to reduce shipping costs. However, the reduction of frame height causes clearance (space for accommodating the height of a component) challenges for alternating current (AC) modules which can have thick AC Microinverters (ACMIs) installed thereon. In addition, challenges to avoiding module damage can be presented by forces that are typically encountered during the preparation, shipping and transportation of packages such as from the weight of pallet double stacking, vibrations, drop impact loads, and side loads.

Approaches that overcome the challenges of the previous approaches are disclosed herein. As part of a one embodiment, module packaging pieces are disclosed. In one embodiment, a packaging piece includes: a first side that includes: one or more flange securing tabs; and a first channel that is configured to accommodate a flange of a first module, and a second side that includes: a second channel that is configured to accommodate a flange of a second module.

In addition, in one embodiment, a module packaging piece includes a first side that includes: a plurality of tapered structures; and a first channel that is configured to accommodate a component of a first module frame, and a second side that includes: a second channel that is configured to accommodate a component of a second module frame; and a securing component that is configured to attach the packaging piece to the second module frame.

In one embodiment, the packaging pieces include a frame-to-frame corner piece and a glass-to-glass corner piece that are provided for packaging alternating current (AC) modules with either reduced frame height or conventional frame height. In one embodiment, when employing the corner pieces, the modules can be stacked horizontally on a pallet parallel to the ground. In one embodiment, the modules can be stacked to alternate sunny side up and sunny side down in the stack to provide clearance for the ACMI between the backsheets of the sunny side up and sunny side down modules (that share a frame-to-frame interface). In one embodiment, as regards bifacial modules, clearance is provided for the ACMI between the back side glass of the sunny side up and sunny side down modules. In one embodiment, the glass-to-glass corner pieces can be positioned between modules that share a glass-to-glass interface, and the frame-to-frame corner pieces can be positioned between the frames of modules that share a frame-to-frame interface. The packaging pieces resist the forces of vibration, drop impact loads, and side loads that are encountered during shipping, and keep modules stably stacked. Conventional module packaging includes vertical module packaging that uses carton braces to achieve module stability. However, such methods may inadequately restrict modules leaving them prone to damage and movement that can cause injury when they are removed one at a time. Vertical packaging also presents challenges for partial pallet shipments because the center of gravity of modules must be precisely controlled on the pallet to maintain package stability. In contrast, a horizontal package provides a centered center of gravity that is inherently stable regardless of the number of modules that are stacked. Consequently, the stable horizontal packaging that is enabled by the frame-to-frame and glass-to-glass packaging pieces described herein provides clearance for the ACMIs in modules with reduced frame height, provides protection against damage to modules during transport and allows the removal of individual modules without the risk of injury from package instability.

### Module Packaging

FIGS. 1A and 1B show short side and long side perspectives of a solar panel module stack 100 that uses an alternating sunny side up and sunny side down arrangement of modules according to one embodiment. FIG. 1A shows a short side perspective view of solar panel module stack 100 that includes modules 101₁-101ₙ, frame to frame packaging pieces F103, glass-to-glass packaging pieces G103 and pallet 111. In addition, FIG. 1A shows module glass components A₁-Aₙ, first short side module frame components B₁(B1₁)-Bₙ(B1ₙ) and ACMIs C₁-Cₙ. FIG. 1B shows along side perspective view of solar panel module stack 100 that includes modules 101₁-101ₙ, frame-to-frame packaging pieces F103, glass-to-glass packaging pieces G103 and pallet 111. In addition, FIG. 1B shows first long side module frame components B₁(B4₁)-Bₙ(B4ₙ) and ACMIs C₁-Cₙ. In the FIG. 1A embodiment, the modules 101₁-101ₙ are stacked using frame-to-frame packaging pieces F103 and glass-to-glass packaging pieces G103 on pallet 111.

Referring to FIG. 1A, modules 101₁-101ₙ include solar panel modules that are stacked horizontally. In one embodiment, the modules are stacked manually. In other embodiments, the modules can be stacked using non-manual processes. In one embodiment, the glass components A₁-Aₙ of the modules 101₁-101ₙ are on the “sunny side” of the module. In one embodiment, the frame components B₁-Bₙ can be coupled to the glass components A₁-Aₙ but can extend in the direction of, and beyond, the backsheet of the module. In one embodiment, the ACMIs C₁-Cₙ that are associated with the modules 101₁-101ₙ can be located on the backsheet side of the modules and can be positioned near an end of such modules.

In one embodiment, the ACMIs C₁-Cₙ can be centered near an end of the modules 101₁-101ₙ with which they are associated. In one embodiment, for modules in the solar panel module stack 100 that share a frame-to-frame interface, the orientation of the individual modules that share the interface is selected such that the ACMI of the sunny side up module and the ACMI of the sunny side down module are located near opposite ends. In one embodiment, because the height of an ACMI can be greater than the height of the frame of the module with which it is associated, this orientation enables the ACMI to extend beyond the space circumscribed by the frame of the module with which it is associated into unoccupied space circumscribed by the frame of the module with which its module shares a frame-to-frame interface.

This is illustrated in FIG. 1B, which shows a long side perspective of the modules in the solar panel module stack 100 that uses an alternating sunny side up and sunny side down arrangement of modules according to one embodiment. Referring to FIG. 1B, the ACMI C₁ of module 101₁ extends downward beyond the space circumscribed by the frame of the module 101₁ into the space circumscribed by the frame of the module 101₂. And the ACMI C₂ of module 101₂ extends upward beyond the space circumscribed by the frame of the module 101₂ into the space circumscribed by the frame of module 101₁.

FIG. 1C is an exploded view of an alternating sunny side up and sunny side down arrangement of modules that shows relative positions of the modules (including ACMI) and packaging pieces according to one embodiment. FIG. 1C shows the manner in which the ACMI C₁ of module 101₁ extends downward beyond the space circumscribed by the frame of the module 101₁ and the manner in which ACMI C₂ of module 101₂ extends upward beyond the space circumscribed by the frame of the module 101₂ into the space circumscribed by the frame of module 101₁. FIG. 1C also illustrates the role that frame-to-frame packaging pieces (e.g., F103(1)₁₋₂ and F103(4)₁₋₂) and glass-to-glass packaging pieces (e.g., G103(1)₂₋₃ and G103(4)₂₋₃) play as a facilitator of the alternating frame-to-frame and glass-to-glass arrangement of modules which enable a reduction in frame height for ACMI modules.

Referring again to FIG. 1A, in one embodiment, frame-to-frame packaging pieces F103 include a plurality of sets of four frame-to-frame packaging pieces, that are positioned between the frames of sunny side up and sunny side down modules of modules 101₁-101ₙ. Some of these frame-to-frame packaging pieces F103 are not visible in FIG. 1A but have a design and utility that is like those that are shown. FIG. 1D illustrates the relative positions of an exemplary set of four frame-to-frame packaging pieces F103(1)-F103(4) with respect to the frame (viewed from the backsheet side) of a sunny side up module such as sunny side up module 101₁ shown in FIG. 1A. Referring to FIG. 1D, the profiles of the left top corner frame-to-frame packaging piece F103(1), right top corner frame-to-frame packaging piece F103(2), right bottom corner frame-to-frame packaging piece F103(3), and left bottom corner frame-to-frame packaging piece F103(4), are shown positioned with respect to the frame (viewed from the backsheet side) of a sunny side up module. Thus, using the reference scheme of FIG. 1D, the sets of four frame-to-frame packaging pieces associated with modules 101₁-101₁ shown in FIG. 1A (including those that are not shown) are identified as F103(1-4)₁₋₂, F103(1-4)₃₋₄, F103(1-4)₅₋₆, F103(1-4)₇₋₈. In one embodiment, as described herein, the subscripts indicate the modules between which the packaging pieces are positioned. In addition to the relative positions of the packaging pieces F103(1), F103(2), F103(3), and F103(4), FIG. 1D also shows the relative positions of the frame components of module 101₁ including first short side frame B1₁, first long side frame B2₁, second short side frame B3₁, and second long side frame B4₁ (second short side frame and first long side frame B2₁ not visible in FIGS. 1A and 1B).

In one embodiment, glass-to-glass packaging pieces G103 include a plurality of sets of four glass-to-glass packaging pieces, that are positioned between the glass components of sunny side down and sunny side up modules of modules 101₂-101ₙ. Some of the glass-to-glass packaging pieces G103 are not visible in FIG. 1A but have a design and utility that is like those that are shown. FIG. 1E illustrates the relative positions of an exemplary set of four glass-to-glass packaging pieces G103(1)-G103(4) with respect to the glass component of a sunny side down module such as sunny side down module 101₂ shown in FIG. 1A. Referring to FIG. 1E, the profiles of the left top corner piece G103(1), right top corner piece G103(2), right bottom corner piece G103(3), and left bottom corner piece G103(4), are shown positioned relative to the glass side of a sunny side down module. Thus, using the reference scheme of FIG. 1E, the sets of four glass-to-glass package pieces positioned between modules 101₂ and 101₃, 101₄ and 101₅, and 101₆ and 101₇ shown in FIG. 1A (including those that are not shown) are identified as G103(1-4)₂₋₃, G103(1-4)₄₋₅, and G103(1-4)₆₋₇.

Referring again to FIG. 1A, frame-to-frame packaging pieces F103(1-4)₁₋₂, F103(1-4)₃₋₄, F103(1-4)₅₋₆, F103(1-4)₇₋₈—only F103(1 and 4)₁₋₂, F103(1 and 4)₃₋₄, F103(1 and 4)₅₋₆, F103(1 and 4)₇₋₈ are visible—and glass-to-glass packaging pieces G103(1-4)₂₋₃, G103(1-4)₄₋₅, and G103(1-4)₆₋₇—only G103(1 and 4)₂₋₃, G103(1 and 4)₄₋₅, and G103(1 and 4)₆₋₇ are visible—facilitate the packaging of modules using the described alternating frame-to-frame and glass-to-glass arrangement of modules according to one embodiment. In particular, in one embodiment, frame-to-frame packaging pieces F103(1-4)₁₋₂, F103(1-4)₃₋₄, F103(1-4)₅₋₆, and F103(1-4)₇₋₈ and glass to glass packaging pieces G103(1-4)₂₋₃, G103(1-4)₄₋₅, and G103(1-4)₆₋₇ enable an arrangement of modules that provides clearance for the ACMI₁₋ₙ in the spaces formed between the backsheets of frame-to-frame oriented modules. In one embodiment, the frame-to-frame packaging pieces F103(1-4)₁₋₂, F103(1-4)₃₋₄, F103(1-4)₅₋₆, and F103(1-4)₇₋₈ can be attached to the bottom flanges of the frames of modules 101₂, 101₄, 101₆ and 101₈ that are positioned sunny side down and provide a frame channel to fit the bottom flange of the frames of modules 101₁, 101₃, 101₅ and 101₇ of modules positioned sunny side up. In one embodiment, frame-to-frame packaging pieces F103(1-4)₁₋₂, F103(1-4)₃₋₄, F103(1-4)₅₋₆, and F103(1-4)₇₋₈ can be snap fitted to the bottom flanges of the frame of modules 101₂, 101₄, 101₆ and 101₈ positioned sunny side down using a frame flange securing mechanism (see description below). Moreover, in one embodiment, the upwardly directed frame channels of the frame-to-frame packaging pieces F103(1-4)₁₋₂, F103(1-4)₃₋₄, F103(1-4)₅₋₆, and F103(1-4)₇₋₈ are designed to securely hug the bottom flanges of the modules 101₁, 101₃, 101₅ and 101₇ that are positioned sunny side up to prevent movement of these modules in the x and y direction (to prevent lateral movement of the modules relative to one or more of the other modules in the stack of horizontally oriented modules). In particular, in one embodiment, package pieces F103(1-4)₁₋₂, F103(1-4)₃₋₄, F103(1-4)₅₋₆, and F103(1-4)₇₋₈ prevents the movement of the modules 101₁, 101₃, 101₅ and 101₇ by providing a force that opposes the forces that can act on the module during handling or transport to cause movement.

The glass-to-glass packaging pieces G103(1-4)₂₋₃, G103(1-4)₄₋₅, and G103(1-4)₆₋₇ are configured to be attached to a catch feature that is part of the design of the module frame. In one embodiment, the glass-to-glass packaging pieces G103(1-4)₂₋₃, G103(1-4)₄₋₅, and G103(1-4)₆₋₇ can be snap fitted to the catch feature of the module frame (see description below) of sunny side up modules 101₃, 101₅ and 101₇ and provide a upwardly directed channel to tightly hug the lips of the frames of sunny side down modules 101₂, 101₄, 101₆ and 101₈. In one embodiment, the glass-to-glass packaging pieces G103(1-4)₂₋₃, G103(1-4)₄₋₅, and G103(1-4)₆₋₇ prevent movement of the sunny side down modules 101₂, 101₄, 101₆ and 101₈ that are positioned above the sunny side up modules 101₃, 101₅ and 101₇ to which they are attached in the x and y direction (prevent lateral movement of the modules relative to one or more of the other modules in the stack of horizontally oriented modules). In one embodiment, the packaging pieces G103(1-4)₂₋₃, G103(1-4)₄₋₅, and G103(1-4)₆₋₇ prevents the movement of the sunny side down modules 101₂, 101₄, and 101₆ positioned above the sunny side up modules 101₃, 101₅ and 101₇ to which they are attached by providing a force sufficient to prevent movement of the sunny side down modules 101₂, 101₄, and 101₆ that opposes forces that can act on the modules during handling and transport.

Referring again to FIG. 1A, an exemplary positioning of each of the modules of the alternating sunny side up and sunny side down arrangement of modules having reduced frame height in the solar panel module stack 100 is illustrated. For example, the solar panel module stack 100 includes topmost module 101₁ that is positioned sunny side up above the module 101₂ which is positioned sunny side down. This alternating sunny side up and sunny side down module arrangement places the frame B₁ of sunny side up module 101₁ above the frame B₂ of the sunny side down module 101₂. Thus, a frame-to-frame interface is formed where the frame of the sunny side up module 101₁ and the frame of the sunny side down module 101₂ are coupled by frame-to-frame packaging pieces (e.g., F103₁₋₂). Positioned underneath sunny side down module 101₂ in the stack is sunny side up module 101₃. Based on this positioning, a glass-to-glass interface is formed where the glass A₂ of sunny side down module 101₂ and the glass A₃ of sunny side up module 101₃ are coupled by glass-to-glass packaging pieces (e.g., G103₂₋₃). Positioned underneath sunny side up module 101₃ in the stack is sunny side down module 101₄. Based on this positioning, a frame-to-frame interface is formed where the frame B₃ of sunny side up module 101₃ and the frame B₄ of sunny side down module 101₄ are coupled by frame-to-frame packaging pieces (e.g., F103₃₋₄). Positioned underneath sunny side down module 101₄ in the stack is sunny side up module 101₅. Based on this positioning, a glass-to-glass interface is formed where the glass A₄ of sunny side down module 101₄ and the glass A₅ of sunny side up module 101s are coupled by glass-to-glass packaging pieces (G103₄₋₅). Positioned underneath sunny side up module 101s in the stack is sunny side down module 101₆. Based on this positioning, a frame-to-frame interface is formed where the frame B₅ of sunny side up module 101s and the frame B₆ of sunny side down module 101₆ are coupled by frame-to-frame packaging pieces (e.g., F103₅₋₆). Positioned underneath sunny side down module 101₆ in the stack is sunny side up module 101₇. Based on this positioning, a glass-to-glass interface is formed where the glass A₆ of sunny side down module 101₆ and the glass A₇ of sunny side up module 101₇ are coupled by glass-to-glass packaging pieces (e.g., G103₆₋₇). Positioned underneath sunny side up module 101₇ in the stack is sunny side down module 101₈. Based on this positioning, a frame-to-frame interface is formed where the frame B₇ of sunny side up module 101₇ and the frame B₈ of sunny side down module 101₈ are coupled by frame-to-frame packaging pieces (e.g., F103₇₋₈).

In one embodiment, based on the exemplary arrangement of modules, each pair of reduced frame height modules in the module stack 100 that share a frame-to-frame interface provides the clearance necessary to accommodate thick ACMIs between their backsheets. Thus, a reduction in module frame height and an increase in module shipping density is enabled. In one embodiment, the increased module shipping density enables a reduction in module shipping cost.

### Packaging Pieces

### Frame-to-Frame Packaging Pieces

FIG. 1F and FIG. 1G show perspective views of an exemplary frame-to-frame packaging piece F103 according to an embodiment of the invention. In particular, FIG. 1F shows features of a first side of the frame-to-frame packaging piece F103 which includes bottom flange securing tabs F103a, bottom frame flange channel F103b, inner walls of frame channel F103c and outer walls of frame channel F103d. And FIG. 1G shows features of a second side of the frame-to-frame packaging piece F103, which include bottom flange frame channel F103e, inner walls of frame channel F103f, outer walls of frame channel F103g, and lead in feature F103h.

Referring to FIG. 1F, bottom flange securing tabs F103a are small flaps or strips of material of the frame-to-frame packaging piece F103 that project upward from the frame-to-frame packaging piece F103 at a slight angle. In one embodiment, the bottom flange securing tabs F103a are configured to facilitate the attachment of the frame-to-frame packaging piece F103 to the bottom flange of the lower module (the module with a sunny side down orientation) of a pair of modules with a frame-to-frame orientation. In one embodiment, to fit the frame-to-frame packaging piece F103 onto the bottom flange of the lower module of a pair of modules with a frame-to-frame orientation, the bottom flange securing tabs F103a can be deflected. In one embodiment, based on the deflection, the frame-to-frame packaging piece F103 can be caused to slide into a desired position on the bottom flange and snap fitted into place. In one embodiment, the flange securing tabs F103a prevent the frame-to-frame packaging piece F103 from falling off the module to which it is attached when the module is handled.

Bottom frame flange channel F103b includes shallow trenches that are formed in the packaging piece F103 and are configured to tightly hug bottom frame flanges. In one embodiment, the bottom frame flange channel F103b can include perpendicular regions that are designed to accommodate the corner flanges of a module frame. In one embodiment, the bottom frame flange channel F103b is configured to hug the bottom frame flanges of the lower module (the module with a sunny side down orientation) of a pair of modules with a frame-to-frame orientation. In one embodiment, the bottom frame flange channel F103b hugs the bottom frame flange on the outside and the inside to prevent movement in the x and the y direction (to prevent lateral movement of the module relative to one or more of the other modules in a stack of horizontally oriented modules).

Inner walls of frame channel F103c are the inner sidewalls of the bottom frame flange channel F103b. The inner walls of frame channel F103c are configured to firmly hug the frame flanges of the lower module (the module with a sunny side down orientation) of a pair of modules with a frame-to-frame orientation. In particular, in one embodiment, inner walls of frame channel F103c are configured to prevent movement in a first sidewise direction when a module stack (e.g., 100 in FIG. 1A) is handled or during transport. Outer walls of frame channel F103d are the outer sidewalls of the bottom frame flange channel F103b. The outer walls of frame channel F103d are configured to firmly hug the frame flanges of the lower module (the module with a sunny side down orientation) of a pair of modules with a frame-to-frame orientation. In particular, in one embodiment, outer walls of frame channel F103d are configured to prevent movement in a second sidewise direction when a package is handled or during transport.

Referring to FIG. 1G, bottom frame flange channel F103e is a shallow trench with perpendicular regions that are formed on the side of frame-to-frame packaging piece F103 opposite that of bottom frame flange channel F103b. In one embodiment, the bottom frame flange channel F103e is configured to hug bottom frame flanges of the upper module (the module with a sunny side up orientation) of a pair of modules with a frame-to-frame orientation. In particular, in one embodiment, the bottom frame flange channel F103e hugs the bottom frame flange on the outside and the inside to prevent movement in the x and the y direction (to prevent lateral movement of the module relative to one or more of the other modules in a stack of horizontally oriented modules).

Inner walls of frame channel F103f are the inner sidewalls of the bottom frame flange channel F103e. The inner walls of frame channel F103f are configured to firmly hug the frame flanges of the upper module (the module with a sunny side up orientation) of a pair of modules with a frame-to-frame orientation. In particular, in one embodiment, the inner walls of frame channel F103f are configured to prevent movement in a first sidewise direction when a module stack is handled or during transport. Outer walls of frame channel F103g are the outer sidewalls of the bottom frame flange channel F103e. The outer walls of frame channel F103g are configured to firmly hug the frame flanges of the upper module (the module with a sunny side up orientation) of a pair of modules with a frame-to-frame orientation. In particular, in one embodiment, outer walls of frame channel F103g are configured to prevent movement in a second sidewise direction when a package is handled or during transport.

Lead in feature F103h is a module guide structure formed on the corner of the frame-to-frame packaging piece F103 and extends in first and second directions along first and second sides of the packaging piece F103. In one embodiment, the lead in feature F103h is configured to guide a module into place, above the module to which frame-to-frame packaging piece F103 is attached, on top of a module stack (e.g., 100 in FIG. 1A). In one embodiment, the lead in feature F103h can be optional.

### Glass-to-Glass Packaging Pieces

FIGS. 1H, 1I and 1J show perspective views of a glass-to-glass packaging piece G103 according to one embodiment of the invention. In particular, FIGS. 1H, 1I and 1J show features of the glass-to-glass packaging piece G103 that includes catch feature G103a (FIG. 1H), piece removal feature G103b (FIG. 1H), frame lip channel G103c (FIG. 1H), inner walls of frame lip channel G103d (FIG. 1H), outer walls of frame lip channel G103e (FIG. 1H), frame lip channel G103f (FIG. 1H), inner walls of frame lip channel G103g (FIG. 1H), outer walls of frame lip channel G103h (FIG. 1H), ribs G103i (FIG. 1I), and lead in feature G103g (FIG. 1J).

Referring to FIG. 1H, catch feature G103a is a clamping feature that includes a part that extends downward from the glass-to-glass packaging piece G103 and a part that extends underneath the glass-to-glass packaging piece G103. In one embodiment, the catch feature G103a is configured to attach the glass-to-glass packaging piece G103 to a module frame. In one embodiment, the catch feature G103a can be snap fitted onto the module frame such that it does not fall off the module frame during handling or transport. Removal feature G103b extends downward from catch feature G103a and is configured to be readily grasped for purposes of facilitating the removal of the glass-to-glass packaging piece G103.

Referring to FIG. 1H, frame lip channel G103c is a shallow trench with perpendicular parts that are formed in a first side of the glass-to-glass packaging piece G103. In one embodiment, the frame lip channel G103c is configured to securely hug the lip of a module frame. In one embodiment, the frame lip channel G103c is configured to hug the lip of a module frame of the upper module (the module with a sunny side down orientation) of a pair of modules with a glass-to-glass orientation. In one embodiment, the frame lip channel G103c hugs the outside and the inside of the lip of the module frame to prevent movement in the x and the y direction (to prevent lateral movement of the module relative to one or more of the other modules in a stack of horizontally oriented modules).

Inner walls of frame lip channel G103d are the inner sidewalls of the frame lip channel G103c. The inner walls of frame lip channel G103d are configured to firmly constrain movement of the frame lips of the upper module (the module with a sunny side down orientation) of a pair of modules with a glass-to-glass orientation. In particular, in one embodiment, inner walls of frame lip channel G103d are configured to prevent movement in a first sidewise direction when a module stack is handled or during transport. Outer walls of frame lip channel G103e are the outer sidewalls of the frame lip channel G103c. The outer walls of frame lip channel G103e are configured to firmly constrain outward movement of the lips of the upper module (the module with a sunny side down orientation) of a pair of modules with a glass-to-glass orientation. Thus, in one embodiment, outer walls of frame lip channel G103e are configured to prevent movement in a second sidewise direction when a module stack is handled or during transport.

Frame lip channel G103f is a shallow trench with perpendicular parts that is formed in the glass-to-glass packaging piece G103 on the side opposite that of frame lip channel G103c. In one embodiment, frame lip channel G103f is configured to hug the frame lip to prevent movement of the frame in the x and y direction (laterally). In one embodiment, the frame lip channel G103f hugs the frame lip on the outside and the inside to prevent movement. In one embodiment, the frame lip channel G103f is configured to hug the frame lip of the lower module (the module with a sunny side up orientation) of a pair of modules with a glass-to-glass orientation.

Inner walls of frame lip channel G103g are the inner sidewalls of the frame lip channel G103f. The inner walls of frame lip channel G103g are configured to firmly constrain movement of the frame lip of the lower module (the module with a sunny side up orientation) of a pair of modules with a glass-to-glass orientation. In particular, in one embodiment, inner walls of frame lip channel G103g are configured to prevent movement in a first sidewise direction when a module stack is handled or during transport. Outer walls of frame lip channel G103h are the outer sidewalls of the frame lip channel G103f. The outer walls of frame lip channel G103h are configured to firmly constrain movement of the frame lip of the lower module (the module with a sunny side up orientation) of a pair of modules with a glass-to-glass orientation. In particular, in one embodiment, outer walls of frame lip channel G103h are configured to prevent movement in a second sidewise direction when a module stack is handled or during transport.

Referring to FIG. 1I, ribs G103i include a plurality of raised and parallel structures onto which the glass surface of a module can be placed. In one embodiment, the ribs G103i can include tapered structures that are designed to accommodate glass deflections. In other embodiments, the ribs G103i can have other geometries and/or include other structures. In one embodiment, accommodating glass deflections can include allowing movement of the glass, that if resisted could result in a breakage or other damage to the glass. Thus, the ribs G103i, by accommodating glass deflections in this manner, operate to prevent damage to the glass. In other embodiments, other structures for accommodating glass deflections can be used. In one embodiment, the ribs G103i can be formed from the same material as the rest of the glass-to-glass packaging piece. In other embodiments, the ribs G103i can be formed from other material. In one embodiment, the other material can be selected to maximize the capacity of the ribs G103i to accommodate glass deflections. In other embodiments, the material may not be selected to maximize the capacity of the ribs G103i to accommodate glass deflections.

Lead in feature G103j (FIGS. 1I and 1J) is a structure formed on the corner of the glass-to-glass packaging piece and extends in first and second directions along first and second sides of the packaging piece. In one embodiment, the lead in feature G103j is configured to guide a module being positioned on top of the glass-to-glass packaging piece G103 into place. In one embodiment, the lead in feature G103j can be optional.

### Operation

In operation, referring to FIG. 1B, when modules 101₁-101ₙ are stacked using the frame-to-frame packaging pieces F103 and glass-to-glass packaging pieces G103 described herein, even where the frame height of the modules has been reduced to increase shipping density, space is created for the ACMI C₁-Cₙ of each module to extend beyond the space circumscribed by the frame of its own module into the space circumscribed by the frame of the module with which its module has a frame-to-frame interface. In addition, when packaging pieces such as frame-to-frame packaging pieces F103 and glass-to-glass packaging pieces G103, have been attached to the module frames B1-Bₙ, and the modules stacked, packaging pieces (e.g., F103 and G103) act to restrict the movement of the modules in the x and y direction so as to protect them from damage during shipping and transport.

FIG. 1K shows a cross-section of an exemplary module frame 150 according to one embodiment. In one embodiment, the module frame 150 includes lip 151, flange 153, mount 155 and mount 157. The way the movement of stacked modules is restricted is illustrated in FIG. 1L which shows a cross-sectional view of a short side of a stack of modules such as that shown in FIG. 1A through frame-to-frame packaging pieces and module frames (such as exemplary module frame 150 in FIG. 1L). Referring to FIG. 1L, the superimposed arrow indicates the direction of an exemplary force on the module 101ₙ₋₁ that is located above the module 101ₙ to which frame-to-frame packaging pieces F103(1) and F103(2) are attached (a force such as may be exerted during the transport or the handling of the modules). If this force is not countered, it can cause the module 101ₙ₋₁ to move relative to the module 101₁ such that a risk of injury, such as to field crew members, or damage to the modules, is posed. FIGS. 1M and 1N show the reaction forces supplied by the frame-to-frame packaging pieces F103(1) and F103(2) that are located at the corners of the module 101₁ of the module stack in response to forces acting on the module 101ₙ₋₁ above the module 101ₙ that is positioned on frame-to-frame packaging pieces F103(1) and F103(2). FIGS. 1L, 1M and 1N show the way frame-to-frame package pieces F103(1) and F103(2) provide reaction forces that operate to keep the module stack stable in response to forces that act on the module stack.

FIG. 1O shows a cross-sectional view of a short side of a module stack such as that shown in FIG. 1A through glass-to-glass pieces, frame-to-frame package pieces and module frames. Referring to FIG. 1O, the superimposed arrow indicates the direction of the force from the module 101ₙ₋₂ that is located above module 101ₙ₋₁ to which glass-to-glass package pieces G103(1) and G103(2) are attached. If this force is not countered, it can cause the module 101ₙ₋₂ to move relative to module 101ₙ₋₁ such that a risk of injury (such as to field crew members) and/or damage to the modules is posed. FIGS. 1P and 1Q show the reaction forces supplied by the glass-to-glass package pieces G103(1) and G103(2) that are located at the corners of module 101n−1 of the module stack in response to forces acting on the module 101n−2 above the module 101n−1 that is positioned on package pieces G103(1) and G103(2). FIGS. 1O, 1P and 1Q show the way glass-to-glass package pieces G103(1) and G103(2) provide reaction forces that operate to keep the module stack stable in response to the forces that act on the stacked modules.

In one embodiment, the packaging pieces resist the force of vibrations, drop impact loads, and side loads during shipping, and maintain the modules in a stable condition on the pallet. Moreover, in one embodiment, packaging pieces F103 and G103 direct stress away from the horizontally stacked modules to prevent damage to the modules.

In one embodiment, the packaging piece design enables horizontal module packaging that provides greater package stability than does vertical packaging. In one embodiment, the stable horizontal module packaging allows field crews to remove one module at a time without the risk of pallet instability. In one embodiment, the preparation of partial packages, such as for residential product shipment, is straightforward, because a partial quantity of modules can be packaged readily from a stable horizontal orientation.

In one embodiment, the packaging pieces F103 and G103 enable AC modules to be shipped at high density because of the reduced module frame height that they facilitate. In one embodiment, the packaging pieces F103 and G103 use less material than conventional packaging piece designs (e.g., conventional plastic corner piece designs) which can have a height that is equal to that of the module frame. For example, conventional packaging pieces can have a height of more than 30 mm. In contrast, in one embodiment, the packaging pieces F103 and G103 can have a thickness of 1 to 2 mm and a height of 12 mm. In other embodiments, the packaging pieces F103 and G103 can have other thicknesses and heights.

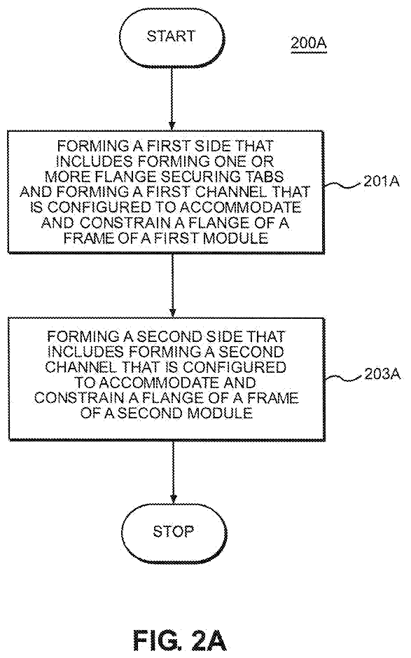

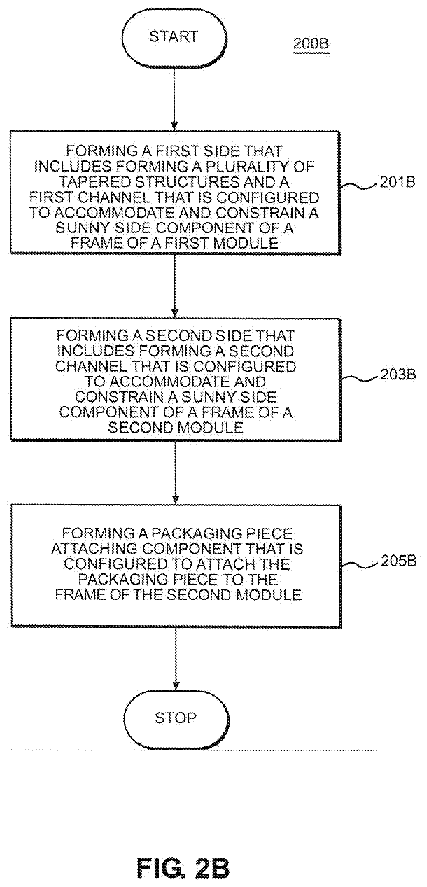

FIG. 2A shows a flowchart 200A of a method of forming a packaging piece according to one embodiment. The method includes, at 201A, forming a first side that includes forming one or more flange securing tabs; and forming a first channel that is configured to accommodate and constrain a flange of a frame of a first module, and at 203A, forming a second side that includes: forming a second channel that is configured to accommodate and constrain a flange of a frame of a second module. In one embodiment, forming the first channel includes forming an inner wall that includes perpendicular parts. In one embodiment, forming the first channel includes forming an outer wall that includes perpendicular parts. In one embodiment, forming the second channel includes forming an outer wall that includes perpendicular parts. In one embodiment, forming the outer wall of the first channel includes forming a module guide structure above the perpendicular parts. In one embodiment, forming the outer wall of the second channel includes forming a module guide structure above the perpendicular parts. In one embodiment, forming the packaging piece includes configuring the packaging piece to accommodate a frame-to-frame orientation of solar panel modules.

FIG. 2B shows a flowchart 200B of a method of forming a packaging piece according to one embodiment. The method includes at 201B, forming a first side that includes forming a plurality of tapered structures and a first channel that is configured to accommodate and constrain a sunny side component of a frame of a first module. At 203B, forming a second side that includes forming a second channel that is configured to accommodate and constrain a sunny side component of a frame of a second module. And at 205B forming a packaging piece attaching component that is configured to attach the packaging piece to the frame of a second module. In one embodiment, forming the first channel includes forming an inner wall that includes perpendicular parts. In one embodiment, forming the first channel includes forming an outer wall that includes perpendicular parts. In one embodiment, forming the second channel includes forming an outer wall that includes perpendicular parts. In one embodiment, forming the outer wall of the first channel includes forming a module guide structure above the perpendicular parts. In one embodiment, forming the outer wall of the second channel includes forming a module guide structure above the perpendicular parts. In one embodiment, forming the packaging piece includes configuring the packaging piece to accommodate a glass-to-glass orientation of solar panel modules.

In one embodiment, a package of modules is disclosed. In one embodiment, the package of modules includes a plurality of horizontally stacked modules and a plurality of first packaging pieces. The plurality of first packaging pieces includes a first side that includes one or more flange securing tabs and a first channel that is configured to accommodate a flange of a first module. And a second side that includes a second channel that is configured to accommodate a flange of a second module. In one embodiment, the package of modules further includes a plurality of second packaging pieces. The plurality of second packaging pieces include a first side that includes a plurality of tapered structures and a first channel that is configured to accommodate a component of a frame of a third module. A second side that includes a second channel that is configured to accommodate a component of a frame of the second module. And a packaging piece attaching component that includes a structure configured to attach the second plurality of packaging pieces to the frame of the second module.

In one embodiment, the first plurality of packaging pieces are located at each corner of at least one of the plurality of horizontally stacked modules. In one embodiment, the second plurality of packaging pieces are located at each corner of at least one of the plurality of horizontally stacked modules. In one embodiment, the first plurality of packaging pieces and the second plurality of packaging pieces are located on opposite sides of each corner of at least one of the plurality of horizontally stacked modules. In one embodiment, the first plurality of packaging pieces and the second plurality of packaging pieces are configured to brace the plurality of horizontally stacked modules. In one embodiment, the first plurality of packaging pieces and the second plurality of packaging pieces are frame-to-frame and glass-to-glass packaging pieces respectively. In one embodiment, the first plurality of packaging pieces and the second plurality of packaging pieces are configured to accommodate a frame-to-frame and a glass-to-glass orientation of solar panel modules.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure. The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The various features of the different embodiments may be variously combined with some features included and others excluded to suit a variety of different applications.

What is claimed is:

1. A packaging piece, comprising:
a first side that includes:
one or more flange securing tabs; and
a first channel that is configured to accommodate and constrain a flange of a frame of a first module, and
a second side that includes:
a second channel that is configured to accommodate and constrain a flange of a frame of a second module.

2. The packaging piece of claim 1, wherein the first channel includes an inner wall that includes perpendicular parts.

3. The packaging piece of claim 1, wherein the first channel includes an outer wall that includes perpendicular parts.

4. The packaging piece of claim 1, wherein the second channel includes an inner wall and an outer wall that includes perpendicular parts.

5. The packaging piece of claim 3, wherein the outer wall of the first channel includes a module guide structure above the perpendicular parts.

6. The packaging piece of claim 4, wherein the outer wall of the second channel includes a module guide structure above the perpendicular parts.

7. The packaging piece of claim 1, wherein the packaging piece is configured to accommodate a frame-to-frame orientation of solar panel modules.

8. A packaging piece, comprising:
a first side that includes:
a plurality of tapered structures; and
a first channel that is configured to accommodate and constrain a sunny side component of a first module frame,
a second side that includes:
a second channel that is configured to accommodate and constrain a sunny side component of a second module frame, and
a packaging piece attaching component that includes:
a component configured to attach the packaging piece to the second module frame.

9. The packaging piece of claim 8, wherein the first channel includes an inner wall that includes perpendicular parts.

10. The packaging piece of claim 8, wherein the first channel includes an outer wall that includes perpendicular parts.

11. The packaging piece of claim 8, wherein the second channel includes an outer wall that includes perpendicular parts.

12. The packaging piece of claim 10, wherein the outer wall of the first channel includes a module guide structure above the perpendicular parts.

13. The packaging piece of claim 11, wherein the outer wall of the second channel includes a module guide structure above the perpendicular parts.

14. The packaging piece of claim 8, wherein the packaging piece is configured to accommodate a glass-to-glass orientation of solar panel modules.

15. A package of modules, comprising:
a plurality of horizontally stacked modules; and
a plurality of first packaging pieces, wherein the plurality of first packaging pieces comprise:
a first side that includes:
one or more flange securing tabs; and
a first channel that is configured to accommodate and constrain a flange of a frame of a first module, and
a second side that includes:
a second channel that is configured to accommodate and constrain a flange of a frame of a second module.

16. The package of modules of claim 15 further comprising a plurality of second packaging pieces wherein the second packaging pieces comprise:
a first side that includes:
a plurality of tapered structures; and
a first channel that is configured to accommodate a sunny side component of a frame of a third module,
a second side that includes:
a second channel that is configured to accommodate a sunny side component of a frame of the second module; and
a packaging piece attaching component that includes:
a structure configured to attach the second plurality of packaging pieces to the frame of the second module.

17. The package of modules of claim 15, wherein the first plurality of packaging pieces are located at each corner of at least one of the plurality of horizontally stacked modules.

18. The package of modules of claim 16, wherein the second plurality of packaging pieces are located at each corner of at least one of the plurality of horizontally stacked modules.

19. The package of modules of claim 16, wherein the first plurality of packaging pieces and the second plurality of packaging pieces are located on opposite sides of each corner of at least one of the plurality of horizontally stacked modules.

20. The package of modules of claim 16, wherein the first plurality of packaging pieces and the second plurality of packaging pieces are configured to brace the plurality of horizontally stacked modules.
